(19) United States
(12) Patent Application Publication
(10) Pub. No.: US 2005/0070090 A1
(43) Pub. Date: Mar. 31, 2005

(54) Method of forming metal pattern using selective electroplating process

(75) Inventors: Hyo-Jong Lee, Seoul (KR); Jong-Won Lee, Seongnam-si (KR); Duk-Ho Hong, Goyang-si (KR); Sang-Rok Hah, Seoul (KR); Hong-Seong Son, Suwon-si (KR); Jin-Sung Chung, Hwaseong-gun (KR); Jae-Soo Ahn, Seoul (KR)

Correspondence Address: Steven M. Mills;MILLS & ONELLO LLP, Suite 605, Eleven Beacon Street, Boston, MA, 02108, US

(73) Assignee: Samsung Electronics Co., Ltd.

(21) Appl. No.: 10/875,434

(22) Filed: Jun. 24, 2004

(30) Foreign Application Priority Data
Sep. 26, 2003 (KR) 03-66934

(51) Int. Cl. H01L 21/48; H01L 21/44; H01L 21/50; H01L 21/4763

(52) U.S. Cl. 438/629; 438/653; 438/656; 438/643; 438/645; 438/634; 438/672

(57) ABSTRACT

A method of forming a metal pattern using a selective electroplating process is provided. First, a dielectric layer is formed on an underlying layer. Then, a trench defining blanket region is formed by patterning the dielectric layer. A diffusion barrier layer is conformally formed in the trench and on the blanket region. A polishing/plating stop layer and an upper seed layer are conformally formed on the diffusion barrier layer in a successive manner. The polishing/plating layer in the blanket region is exposed by selectively removing the upper seed layer in the blanket region, and, at the same time, a seed layer pattern remaining in the trenches is formed. An upper conductive layer is formed to fill the trench surrounded by the seed layer pattern using an electroplating process. Then, the dielectric layer in the blanket region is exposed by planarizing the upper conductive layer, the polishing/plating stop layer, the seed layer pattern, and the diffusion barrier layer.

### CROSS-REFERENCE TO RELATED APPLICATION

This application claims the benefit of Korean Patent Application No. 2003-66934, filed on Sep. 26, 2003, the contents of which are hereby incorporated herein by reference in their entirety.

### BACKGROUND OF THE INVENTION

1. Field of the Invention

The present invention relates to a method of forming a metal pattern of semiconductor devices and, more particularly, to a method of forming a metal pattern using a selective electroplating process.

2. Description of the Related Art

In general, there are two methods of forming metal patterns to be used as metal wiring in semiconductor devices. One of them is a metal deposition and patterning process, being widely used for manufacturing semiconductor devices, while the other is a damascene process by which trenches are formed on a dielectric layer and then the metal patterns are formed within those trenches.

The damascene process, which may be classified as a single damascene process or a dual damascene process, is summarized in accordance with the following. First, the trenches are formed in a dielectric layer using a photolithography process. A plating layer is then formed to fill the trenches using an electroplating process. The metal pattern is formed within the trenches by planarizing the plating layer until the dielectric layer is exposed. The planarization process, being an essential part of the damascene process, is commonly performed by chemical mechanical polishing (hereinafter, referred to as “CMP”).

FIGS. 1 and 2 are cross-sectional views illustrating a procedure of forming metal wiring in accordance with the conventional damascene process.

Referring to FIG. 1, a dielectric layer 102 is formed on an underlying layer 100. The underlying layer 100 may be a semiconductor substrate, metal wiring or a dielectric layer. Then, trenches 104 are formed by patterning the dielectric layer 102. The trenches 104 may have different widths. As a result, the dielectric layer 102 is formed to include a first trench 104a with a wider width, a second trench 104b with a narrower width, and a blanket region 105 without a trench. Then, a conformal diffusion barrier layer 106 and a metal seed layer 108 are formed on the resultant structure including the trenches 104. Subsequently, a plating layer 110 is formed to fill the trenches 104 on the metal seed layer 108.

In the process of forming the plating layer 110, the filling characteristics of the trenches 104 depend on the widths of the trenches. The second trench 104b with the narrower width is rapidly filled by a bottom-up fill method. The first trench 104a with the wider width is filled by a conformal fill method, so that the plating occurs at the same speed as in the blanket region 105. As a result, the plating layer 110 having the same thickness as the step difference of the first trench 104a is formed on the blanket region 105 and the second trench 104b, as shown in FIG. 1.

Referring to FIG. 2, metal wiring 112 is formed within the trenches 104 by polishing the plating layer 110 by a CMP process until the dielectric layer 102 is exposed. However, such a CMP process is regarded to have defects due to dishing and erosion appearing at an upper part of the metal wiring 112, the defects being caused by over-polishing of the metal wiring 112 because the dielectric layer 102 as a polish-stop layer has failed to stop the polishing. This failure is mainly due to a difference in polishing rates between the metal wiring 112 and the dielectric layer 102, as well as due to residues accumulated on a soft polishing pad while polishing. FIG. 2 shows dishing signifying the over-polishing of the metal wiring 112 in the first trench 104a with a wider width, and an erosion signifying the over-polishing of the dielectric layer between the second trenches 104b with the narrower widths because the dielectric layer has failed to function as the polish-stop layer. These dishing/erosion phenomena reduce thickness uniformity of the metal wiring, causing electrical malfunctions, and lower a yield of the semiconductor devices.

A method for reducing the dishing and erosion is taught in Japanese Laid-Open Patent Application No. 2001-345325, entitled “A method for forming wire of semiconductor devices”.

According to the Japanese Patent Application Laid-Open No. 2001-345325, a dielectric layer is formed on a semiconductor substrate, and then a first trench and a second trench with a width smaller than that of the first trench are formed by patterning the dielectric layer. A diffusion barrier layer is formed on the dielectric layer. After that, a first copper plating layer is formed on the diffusion barrier layer, which is subsequently heat-treated to decrease its hardness. Then, a second copper plating layer is formed to fill the trenches on the first copper plating layer, and the CMP process is performed thereon. Different polishing rates due to a hardness difference between the first copper plating layer and the second copper plating layer are used to reduce the dishing and erosion.

Increase of the amount of polishing in the CMP increases polish residues accumulated on the polishing pad, thus increasing the dishing/erosion. That is, the larger the thickness of the plating layer formed on the blanket region 105 and the second trenches 104b, i.e., the greater the step difference between the first trench 104a and the blanket region 105, the larger the amount of dishing/erosion. In a process where a big step difference between a lower part of the trench and the blanket region is created, e.g., in a wiring process of a semiconductor device, in a metal coil forming process of an inductor, or in a fine structure forming process by an LIGA (Lithography, Galvanik, Abformung) process in an MEMS (Micro Electro Mechanical System) manufacturing process, the dishing/erosion may be more serious.

### SUMMARY OF THE INVENTION

The present invention provides a method of forming a metal pattern capable of selectively forming the metal pattern within trenches, of suppressing formation of a metal layer on a blanket region, and of minimizing dishing/erosion by reducing the amount of the metal layer to be planarized in subsequent processes. In order to achieve the above object, the present invention provides a method of forming a metal pattern using a selective electroplating process. The method comprises forming a dielectric layer on an underlying layer. A trench defining a blanket region is formed by patterning the dielectric layer. A diffusion barrier layer is conformally formed in the trench and on the blanket region. A polishing/plating stop layer and an upper seed layer are conformally formed on the diffusion barrier layer in a successive manner. The upper seed layer in the blanket region is selectively removed to expose the polishing/plating stop layer in the blanket region and to simultaneously form a seed layer pattern remaining in the trench. An upper conductive layer is formed to fill the trench surrounded by the seed layer pattern using an electroplating process. The dielectric layer in the blanket region is exposed by planarizing the upper conductive layer, the polishing/plating stop layer, the seed layer pattern and the diffusion barrier layer.

In one embodiment, the diffusion barrier layer is formed of at least one material selected from the group consisting of Ta, TaN, TaAlN, TaSiN, TaSi₂, Ti, TiN, WN and TiSiN.

In one embodiment, the polishing/plating stop layer is formed either of a material layer selected from the group consisting of Ta, TaN, TaAlN, TaSiN, TaSi₂, Ti, TiN, WN and TiSiN, or of a material layer capable of forming a natural oxide layer. The material layer capable of forming a natural oxide layer can be an Al layer.

In one embodiment, the polishing/plating stop layer is formed by a PVD process or a CVD process to have a thickness of 10 Å to 10000 Å.

The upper seed layer is formed of Cu, Pt, Au, Pd, Ag, Ni or an alloy of one or more thereof. In one particular embodiment, the upper seed layer is formed of Cu.

In one embodiment, the upper seed layer is formed by a PVD process or a CVD process to have a thickness of 100 Å to 5000 Å.

In one embodiment, the upper conductive layer is formed of Cu.

In one embodiment, the upper conductive layer, the polishing/plating stop layer, the seed layer pattern and the diffusion barrier layer are planarized using a chemical mechanical polishing (“CMP”) process.

In one embodiment, the method further comprises a step of forming conformally a lower seed layer and a lower conductive layer on the diffusion barrier layer in a successive manner, before the step of forming the polishing/plating stop layer. In one embodiment, the lower seed layer is formed of Cu, Pt, Au, Pd, Ag, Ni or an alloy of one or more thereof. In one particular embodiment, the lower seed layer is formed of Cu. The lower seed layer can be formed by a PVD processor a CVD process to have a thickness of 100 Å to 5000 Å. The lower conductive layer can be formed of Cu. The lower conductive layer can be formed by the electroplating process to have a thickness of 100 Å to 5000 Å.

In one embodiment, the method further comprises a step of performing a pre-polish heat treatment process, before the step of planarizing the upper conductive layer, the polishing/plating stop layer, the seed layer pattern and the diffusion barrier layer.

In accordance with another aspect, the invention is directed to a method of forming a metal pattern, comprising the steps of: (i) forming a dielectric layer on an underlying layer; (ii) patterning the dielectric layer to form a first trench and a second trench defining blanket region, wherein the first trench has a wider width than the second trench; (iii) forming conformally a diffusion barrier layer and a lower seed layer in a successive manner on the resultant structure comprising the trenches; (iv) forming a lower conductive layer on the lower seed layer, wherein the lower conductive layer is formed conformally in the first trench and formed to fill the second trench; (v) forming conformally a polishing/plating stop layer and an upper seed layer in a successive manner on the lower conductive layer; (vi) selectively removing the upper seed layer in the blanket region and over the second trench to expose the polishing/plating stop layer in the blanket region and over the second trench and to simultaneously form a seed layer pattern remaining in the first trench; (vii) filling the trenches surrounded by the seed layer pattern with the upper conductive layer using an electroplating process; and (viii) planarizing the upper conductive layer, the polishing/plating stop layer, the upper seed layer, the lower conductive layer, the lower seed layer and the diffusion layer to expose the dielectric layer.

In one embodiment, the diffusion barrier layer is formed of at least one material selected from the group consisting of Ta, TaN, TaAlN, TaSiN, TaSi₂, Ti, TiN, WN and TiSiN.

In one embodiment, the lower seed layer is made of Cu, Pt, Au, Pd, Ag, Ni or an alloy comprising one or more thereof.

In one particular embodiment, the lower seed layer is formed of Cu.

In one embodiment, the lower seed layer is formed by a PVD process or a CVD process to have a thickness of 100 Å to 5000 Å.

In one embodiment, the lower conductive layer is formed of Cu.

In one embodiment, the lower conductive layer is formed by the electroplating process to have a thickness of 100 Å to 5000 Å.

In one embodiment, the polishing/plating stop layer is formed either of a material layer selected from the group consisting of Ta, TaN, TaAlN, TaSiN, TaSi₂, Ti, TiN, WN and TiSiN, or of a material layer capable of forming a natural oxide layer. The material layer capable of forming a natural oxide can be an Al layer or a Mg layer.

In one embodiment, the polishing/plating stop layer is formed by a PVD process or a CVD process to have a thickness of 10 Å to 10000 Å.

In one embodiment, the upper seed layer is formed of Cu, Pt, Au, Pd, Ag, Ni or an alloy of one or more thereof.

In one particular embodiment, the upper seed layer is formed of Cu.

In one embodiment, the upper seed layer is formed by a PVD process or a CVD process to have a thickness of 100 Å to 5000 521 .

In one embodiment, the upper conductive layer is formed of Cu.

In one embodiment, the upper conductive layer, the polishing/plating stop layer, the upper seed layer, the lower conductive layer, the lower seed layer and the diffusion barrier layer are planarized using a CMP process.

In one embodiment, the method further comprises a step of performing a pre-polish heat treatment process, before the step of planarizing the upper conductive layer, the polishing/plating stop layer, the upper seed layer, the lower conductive layer, the lower seed layer and the diffusion barrier layer.

In one embodiment, the method further comprises patterning the dielectric layer further to form a via hall exposing the underlying layer through the dielectric layer of lower parts of the first trench.

### BRIEF DESCRIPTION OF THE DRAWINGS

The above and other features and advantages of the present invention will become more apparent to those of ordinary skill in the art by describing in detail preferred embodiments thereof with reference to the attached drawings.

FIGS. 1 and 2 are cross-sectional views illustrating a process of forming metal wiring in accordance with the conventional art.

FIGS. 3 to 8 are cross-sectional views illustrating a process of forming a metal pattern in accordance with a first embodiment of the present invention.

FIGS. 9 to 12 are cross-sectional views illustrating a process of forming a metal pattern in accordance with a second embodiment of the present invention.

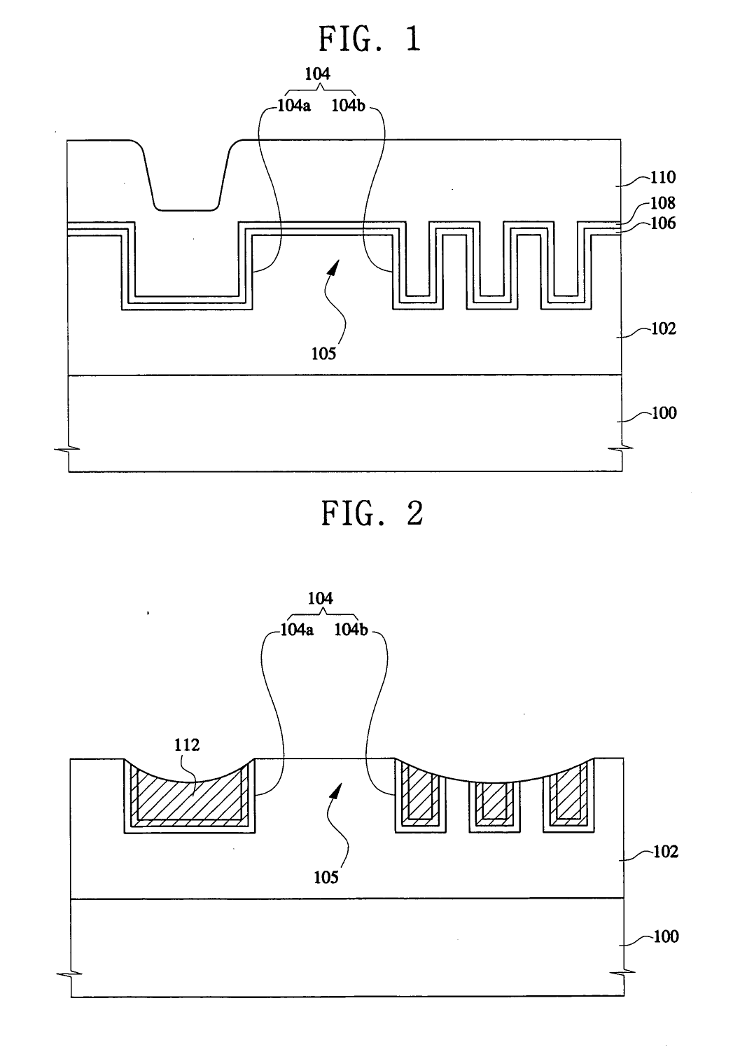

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout the specification.

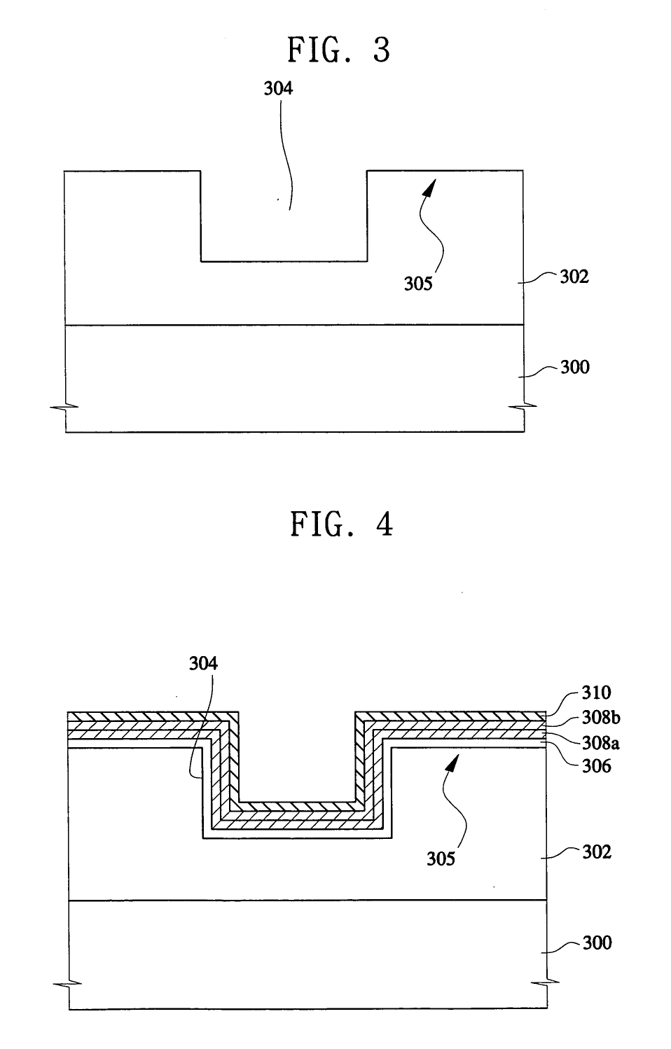

FIGS. 3 to 8 are cross-sectional views illustrating a process of forming a metal pattern in accordance with a first embodiment of the present invention.

Referring to FIG. 3, a dielectric layer 302 is formed on an underlying layer 300. The underlying layer 300 may be a semiconductor substrate, metal wiring or a lower dielectric layer. The dielectric layer 302 may be an interlayer insulating layer or an inter-metal insulating layer. Then, a trench 304 defining a blanket region 305 is formed by patterning the dielectric layer 302. The trench 304 is formed by a photolithography process and may further comprise holes exposing the underlying layer 300 through the dielectric layer 302 of lower parts thereof, although not shown in the drawing. The trench 304 may preferably have a depth of 1000 Å to 50000 Å.

Referring to FIG. 4, a diffusion barrier layer 306 is formed conformally on resultant structure having the trench 304. The diffusion barrier layer 306 may be formed of at least one material selected from the group consisting of Ta, TaN, TaAlN, TaSiN, TaSi₂, Ti, TiN, WN and TiSiN. The diffusion barrier layer 306 may be formed by a PVD method to have a thickness of 50 Å to 1000 Å. Subsequently, a lower seed layer 308a and a lower conductive layer 308b are formed conformally on the diffusion barrier layer 306. The lower seed layer 308a may preferably be, but is not necessarily, formed of Cu. It may also be formed of a conductive material such as Pt, Au, Ag and Ni, or an alloy of one or more thereof. Further, the lower seed layer 308a may be formed by a CVD or PVD process to have a thickness of 100 Å to 5000 Å. The lower conductive layer 308b is made of Cu in the first embodiment of the present invention, and is formed by an electroplating process having superior burying characteristics to have a thickness of 100 Å to 5000 Å.

After that, a polishing/plating stop layer 310 is formed conformally on the lower conductive layer 308b. The polishing/plating stop layer 310 may be formed either of a material layer selected from a group consisting of Ta, TaN, TaAlN, TaSiN, TaSi₂, Ti, TiN, WN and TiSiN, i.e., a material used for the diffusion barrier layer, or by a layer of material capable of forming a natural oxide layer, such as Al or Mg. The polishing/plating stop layer may be formed by the CVD or PVD method to have a thickness of 10 Å to 10000 Å.

In the case in which the diffusion barrier layer 306 functions also as a conductive underlying layer in a successive electroplating process by allowing a current to pass through it, the above processes of forming the lower seed layer 308a and the lower conductive layer 308b may be omitted. In such case, the polishing/plating stop layer 310 may be formed on the diffusion barrier layer 306. However, the lower seed layer 308a as well as the lower conductive layer 308b may preferably be formed for obtaining a plating layer with superior quality and for a smooth progress of the plating process, and, in such case, the lower seed layer 308a and the lower conductive layer 308b function as the conductive underlying layer in the successive electroplating processes.

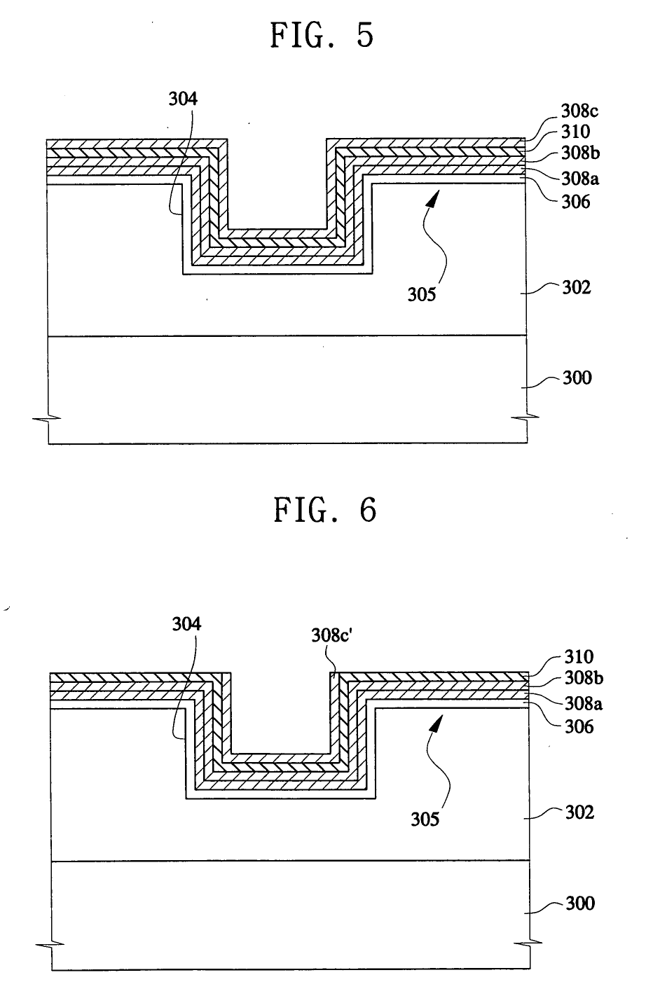

Referring to FIG. 5, an upper seed layer 308c is conformally formed on the polishing/plating stop layer 310. The upper seed layer 308c may preferably be, but is not necessarily, formed of Cu. It may also be formed of a conductive material such as Pt, Au, Ag and Ni, or an alloy of one or more thereof. Further, the upper seed layer 308c may be formed by the CVD or PVD method to have a thickness of 100 Å to 5000 Å.

Referring to FIG. 6, the upper seed layer 308c formed in the blanket region 305 is selectively removed by planarizing the upper seed layer 308c. As a result, the polishing/plating stop layer 310 in the blanket region 305 is exposed, and, at the same time, a seed layer pattern 308c′, which is a remaining part of the upper seed layer 308c, is formed in the trench 304. The planarization process may be performed by the CMP process, wherein the polishing/plating stop layer 310 functions as a polishing termination layer.

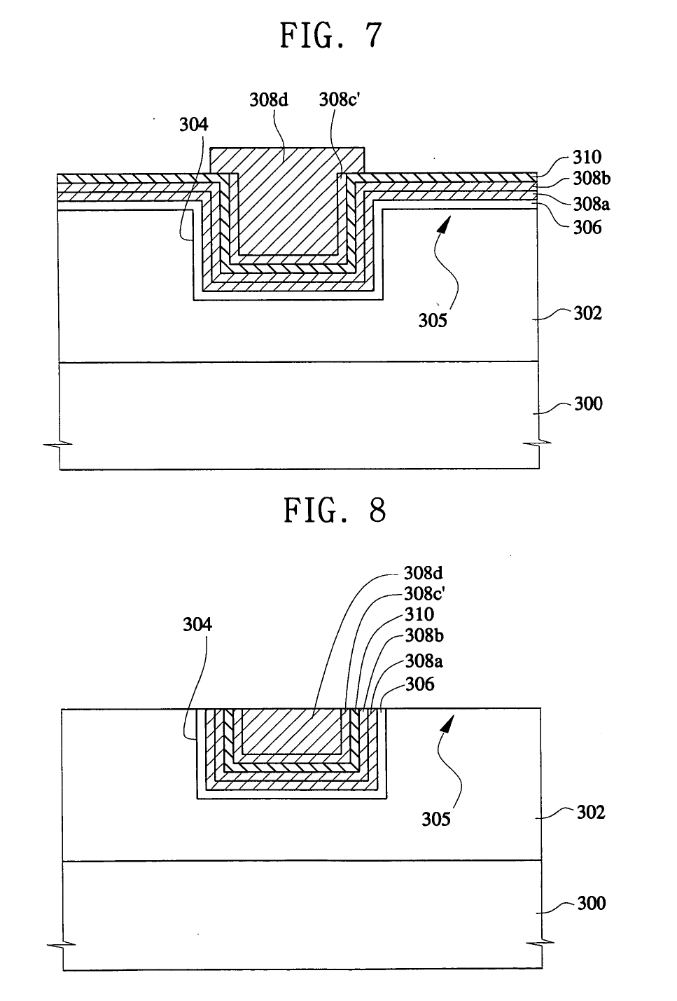

Referring to FIG. 7, an upper conductive layer 308d is formed on the resultant structure exposing the polishing/plating stop layer 310 in the blanket region 305 to fill the trench 304. The upper conductive layer 308d may be formed of Cu. The upper conductive layer 308d may be formed by an electroplating process to have a thickness of 1000 Å to 20000 Å. The polishing/plating stop layer 310 functions also as a plating stop layer in this process, therefore the upper conductive layer 308d is formed selectively on the seed layer pattern 308c′ remaining in the trench 304. In case the polishing/plating stop layer 310 is formed of a material selected from the group consisting of Ta, TaN, TaAlN, TaSiN, TaSi₂, Ti, TiN, WN, and TiSiN as described above, the upper conductive layer 308d to be formed on the blanket region 305 may be minimized due to a difference in nucleation speed with that of the seed layer pattern 308c′ remaining in the trench 304. Furthermore, in case the polishing/plating stop layer 310 is formed of a material layer capable of generating a natural oxide layer, such as Al, Mn, etc. as described above, the natural oxide layer is formed on the polishing/plating stop layer 310 in the process of planarizing the upper seed layer 308c. As a result, the formation of the upper conductive layer 308d on the blanket region 305 may be suppressed, because the electroplating process requires a conductive underlying layer.

Then, the resultant structure with the second conductive layer 308d formed on it, undergoes a pre-polish heat treatment process, for the purpose of lowering the hardness of each conductive layer by re-crystallization thereof, so that the following polishing processes may be readily performed. The pre-polish heat treatment may be performed at a temperature between 20° C. and 300° C. for 1 to 3600 minutes. The pre-polish heat treatment is performed preferably at 200° C. for 5 minutes.

Referring to FIG. 8, an upper surface of the dielectric layer 302 in the blanket region 305 is exposed by successively planarizing the upper conductive layer 308d, the polishing/plating stop layer 310, the seed layer pattern 308c′, the lower conductive layer 308b, the lower seed layer 308a and the diffusion barrier layer 306, using the CMP process. As a result, a metal pattern is formed in the trench 304. In the first embodiment of the present invention, this metal pattern is a copper pattern including a polishing/plating stop layer therein. The metal pattern may be a wiring in a semiconductor device, a metal coil of an inductor, or a fine metal structure formed by an LIGA process of an MEMS manufacturing method.

As described above, due to a presence of the polishing/plating stop layer 310, the second conductive layer 308d is plated selectively within the trench 304 and the plating on the blanket region 315 is suppressed. Therefore, the polishing amount by the CMP process in the succeeding planarization process may be minimized, and thus, the dishing and erosion may also be minimized.

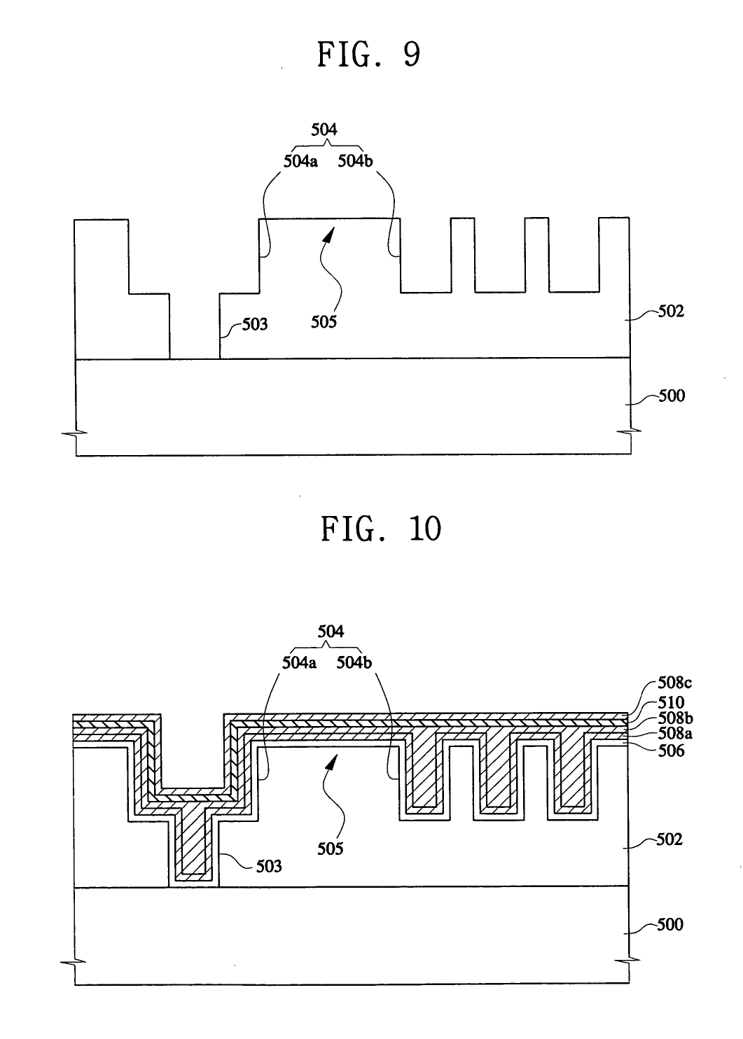

FIGS. 9 to 12 are cross-sectional views illustrating processes of forming a metal pattern in accordance with a second embodiment of the present invention. The materials and methods of forming the layers in the second embodiment of the present invention are similar to their counterparts in the first embodiment of the present invention.

Referring to FIG. 9, a dielectric layer 502 is formed on an underlying layer 500. Then, a first trench 504a and second trenches 504b defining a blanket region 505 are formed by patterning the dielectric layer 502. The first trench 504a has a width wider than the second trenches 504b. The first trench 504a may further comprise a hole 503 exposing the underlying layer 500 through the dielectric layer 502 of a lower part thereof. The hole 503, being a contact hole for exposing the semiconductor substrate or a via hole for exposing the lower wiring, is hereinafter called a “via hole” 503. The trenches 504 and the via hole 503 may be formed by a single damascene process or a dual damascene process.

Referring to FIG. 10, a diffusion barrier layer 506 and a lower seed layer 508a are formed conformally on the resultant structure comprising the trenches 504 and the via hole 503, in a successive manner, as in the first embodiment. Then, a lower conductive layer 508b is formed on the lower seed layer 508a using an electroplating process. In this process, the second trenches 504b with a narrower width and the via hole 503 are rapidly filled by a bottom-up fill method, while the first trench 504a with a wider width is filled by a conformal fill method so that the plating herein occurs at the same speed as in the blanket region 505. As a result, the lower conductive layer 508b is formed conformally along sidewalls and bottom of the first trench 504a, after filling the second trenches 504b and the via hole 503. In addition, the lower conductive layer 508b formed on the blanket region 505 and on the second trenches 504b is of similar thickness. Then, the polishing/plating stop layer 510 and the upper seed layer 508c are formed conformally on the lower conductive layer 508b in a successive manner, as in the first embodiment of the present invention.

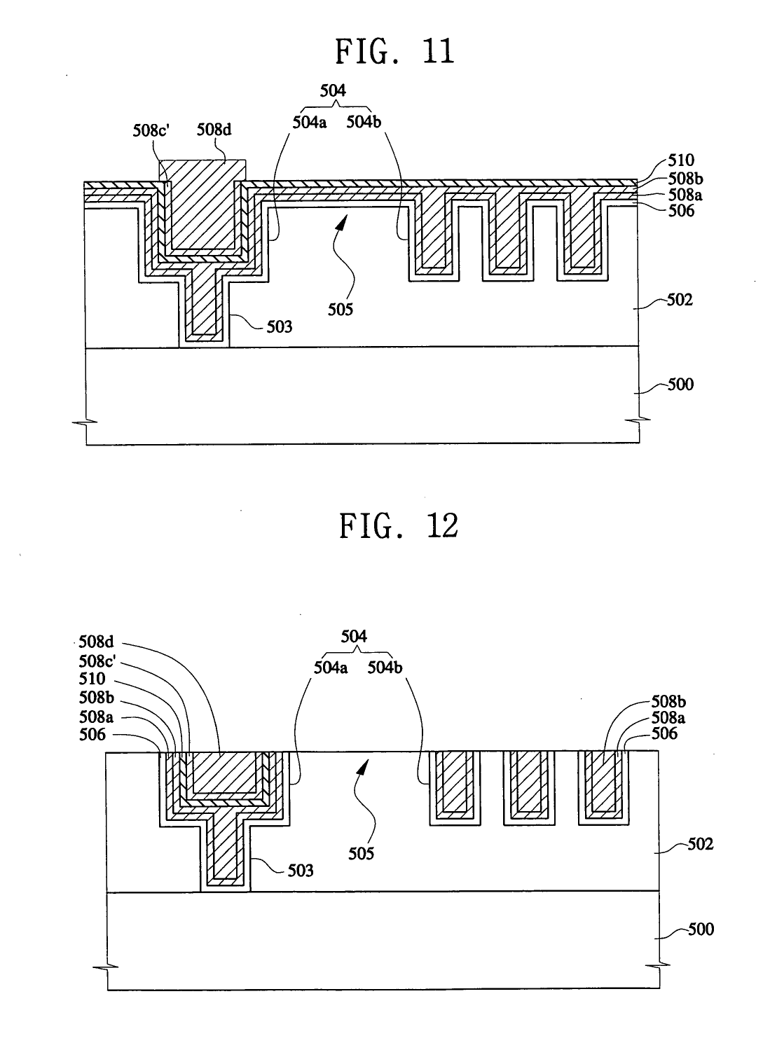

Referring to FIG. 11, the upper seed layer 508c formed in the blanket region 505 and over the second trenches 504b is removed by planarizing the upper seed layer 508c. As a result, the polishing/plating stop layer 510 in the blanket region 505 and over the second trenches 504b is exposed, and the seed layer pattern 508c′, which is a remaining part of the upper seed layer 508c, is formed in the first trench 504a, at the same time. After that, the upper conductive layer 508d is formed on the resultant structure exposing the polishing/plating stop layer 510, as described in the first embodiment of the present invention. The upper conductive layer 508d is plated selectively on the seed layer pattern 508c′ remaining in the first trench 504a, and the plating is suppressed on the blanket region 505 and the second trenches 504b.

Referring to FIG. 12, a metal pattern is formed in the trenches 504 and the via hole 506 by pre-polish heat treatment process and planarization process as in the first embodiment of the present invention. The metal pattern may be metal wiring or a metal plug in a semiconductor device.

As described above, the present invention provides a method of forming a metal pattern capable of selectively forming a metal layer within the trench and of suppressing formation of the metal layer on the blanket regions, and thus, may minimize dishing/erosion by reducing the amount of the metal layer to be planarized in the subsequent processes.

While this invention has been particularly shown and described with reference to preferred embodiments thereof, it will be understood by those skilled in the art that various changes in form and details may be made therein without departing from the spirit and scope of the invention as defined by the appended claims.

1. A method of forming a metal pattern, comprising the steps of:
forming a dielectric layer on an underlying layer;
patterning the dielectric layer to form a trench defining a blanket region;
forming conformally a diffusion barrier layer in the trench and on the blanket region;
forming conformally a polishing/plating stop layer and an upper seed layer in a successive manner on the diffusion barrier layer;
selectively removing the upper seed layer in the blanket region to expose the polishing/plating stop layer in the blanket region and to simultaneously form a seed layer pattern remaining in the trench.
filling the trench surrounded by the seed layer pattern with an upper conductive layer using an electroplating process; and
planarizing the upper conductive layer, the polishing/plating stop layer, the seed layer pattern and the diffusion barrier layer to expose the dielectric layer in the blanket region.

2. The method as set forth in claim 1, wherein the diffusion barrier layer comprises at least one selected from the group consisting of Ta, TaN, TaAlN, TaSiN, TaSi₂, Ti, TiN, WN and TiSiN.

3. The method as set forth in claim 1, wherein the polishing/plating stop layer comprises either a material layer selected from the group consisting of Ta, TaN, TaAlN, TaSiN, TaSi₂, Ti, TiN, WN and TiSiN, or a material layer capable of forming a natural oxide layer.

4. The method as set forth in claim 3, wherein the material layer capable of forming a natural oxide layer is an Al layer or a Mg layer.

5. The method as set forth in claim 1, wherein the polishing/plating stop layer is formed by a PVD process or a CVD process to have a thickness of 10 Å to 10000 Å.

6. The method as set forth in claim 1, wherein the upper seed layer comprises Cu, Pt, Au, Pd, Ag, Ni or an alloy of one or more thereof.

7. The method as set forth in claim 1, wherein the upper seed layer comprises Cu.

8. The method as set forth in claim 1, wherein the upper seed layer is formed by a PVD process or a CVD process to have a thickness of 100 Å to 5000 Å.

9. The method as set forth in claim 1, wherein the upper conductive layer comprises Cu.

10. The method as set forth in claim 1, wherein the upper conductive layer, the polishing/plating stop layer, the seed layer pattern and the diffusion barrier layer are planarized using a chemical mechanical polishing (“CMP”) process.

11. The method as set forth in claim 1, further comprising a step of forming conformally a lower seed layer and a lower conductive layer on the diffusion barrier layer in a successive manner, before the step of forming the polishing/plating stop layer.

12. The method as set forth in claim 11, wherein the lower seed layer comprises at least one of Cu, Pt, Au, Pd, Ag, Ni and an alloy of one or more thereof.

13. The method as set forth in claim 11, wherein the lower seed comprises Cu.

14. The method as set forth in claim 11, wherein the lower seed layer is formed by a PVD process or a CVD process to have a thickness of 100 Å to 5000 Å.

15. The method as set forth in claim 11, wherein the lower conductive layer comprises Cu.

16. The method as set forth in claim 11, wherein the lower conductive layer is formed by the electroplating process to have a thickness of 100 Å to 5000 Å.

17. The method as set forth in claim 1, further comprising a step of performing a pre-polish heat treatment process, before the step of planarizing the upper conductive layer, the polishing/plating stop layer, the seed layer pattern and the diffusion barrier layer.

18. A method of forming metal pattern, comprising the steps of:
forming a dielectric layer on an underlying layer;
patterning the dielectric layer to form a first trench and a second trench defining blanket region, wherein the first trench has a wider width than the second trench;
forming conformally a diffusion barrier layer and a lower seed layer in a successive manner on the resultant structure comprising the trenches;
forming a lower conductive layer on the lower seed layer, wherein the lower conductive layer is formed conformally in the first trench and formed to fill the second trench;
forming conformally a polishing/plating stop layer and an upper seed layer in a successive manner on the lower conductive layer;
selectively removing the upper seed layer in the blanket region and over the second trench to expose the polishing/plating stop layer in the blanket region and over the second trench and to simultaneously form a seed layer pattern remaining in the first trench;
filling the trenches surrounded by the seed layer pattern with the upper conductive layer using an electroplating process; and
planarizing the upper conductive layer, the polishing/plating stop layer, the upper seed layer, the lower conductive layer, the lower seed layer and the diffusion layer to expose the dielectric layer.

19. The method as set forth in claim 18, wherein the diffusion barrier layer is formed of at least one material selected from the group consisting of Ta, TaN, TaAlN, TaSiN, TaSi₂, Ti, TiN, WN and TiSiN.

20. The method as set forth in claim 18, wherein the lower seed layer comprises at least one of Cu, Pt, Au, Pd, Ag, Ni and an alloy comprising one or more thereof.

21. The method as set forth in claim 18, wherein the lower seed layer is comprises Cu.

22. The method as set forth in claim 18, wherein the lower seed layer is formed by a PVD process or a CVD process to have a thickness of 100 Å to 5000 Å.

23. The method as set forth in claim 18, wherein the lower conductive layer comprises Cu.

24. The method as set forth in claim 18, wherein the lower conductive layer is formed by the electroplating process to have a thickness of 100 Å to 5000 Å.

25. The method as set forth in claim 18, wherein the polishing/plating stop layer is formed either of a material layer selected from the group consisting of Ta, TaN, TaAlN, TaSiN, TaSi₂, Ti, TiN, WN and TiSiN, or of a material layer capable of forming a natural oxide layer.

26. The method as set forth in claim 25, wherein the material layer capable of forming a natural oxide is an Al layer or a Mg layer.

27. The method as set forth in claim 18, wherein the polishing/plating stop layer is formed by a PVD process or a CVD process to have a thickness of 10 Å to 10000 Å.

28. The method as set forth in claim 18, wherein the upper seed layer comprises at least one of Cu, Pt, Au, Pd, Ag, Ni and an alloy of one or more thereof.

29. The method as set forth in claim 18, wherein the upper seed layer comprises Cu.

30. The method as set forth in claim 18, wherein the upper seed layer is formed by a PVD process or a CVD process to have a thickness of 100 Å to 5000 Å.

31. The method as set forth in claim 18, wherein the upper conductive layer comprises Cu.

32. The method as set forth in claim 18, wherein the upper conductive layer, the polishing/plating stop layer, the upper seed layer, the lower conductive layer, the lower seed layer and the diffusion barrier layer are planarized using a CMP process.

33. The method as set forth in claim 18, further comprising a step of performing a pre-polish heat treatment process, before the step of planarizing the upper conductive layer, the polishing/plating stop layer, the upper seed layer, the lower conductive layer, the lower seed layer and the diffusion barrier layer.

34. The method as set forth in claim 18, further comprising patterning the dielectric layer further to form a via hall exposing the underlying layer through the dielectric layer of lower parts of the first trench.
